(19) United States
(12) Patent Application Publication
(10) Pub. No.: US 2024/0242934 A1
(43) Pub. Date: Jul. 18, 2024

(54) PLASMA PROCESSING APPARATUS

(71) Applicant: Tokyo Electron Limited, Tokyo (JP)

(72) Inventor: Masaki HIRAYAMA, Fuchu City (JP)

(21) Appl. No.: 18/411,359

(22) Filed: Jan. 12, 2024

(30) Foreign Application Priority Data
Jan. 18, 2023 (JP) 2023-005807

(51) Int. Cl. H01J 37/32

(52) U.S. Cl. CPC H01J 37/32082

(57) ABSTRACT

A plasma processing apparatus includes a chamber, a substrate support provided within the chamber, a discharger provided to discharge an electromagnetic wave into a plasma generation space, and a waveguide part configured to supply the electromagnetic wave to the discharger. The waveguide part includes a resonator that provides a waveguide path, and the resonator includes at least one slit having a longitudinal direction in a propagation direction in which the electromagnetic wave resonating within the resonator propagates in the waveguide path.

### CROSS-REFERENCE TO RELATED APPLICATION

This application is based upon and claims the benefit of priority from Japanese Patent Application No. 2023-005807, filed on Jan. 18, 2023, the entire contents of which are incorporated herein by reference.

### TECHNICAL FIELD

Exemplary embodiments of the present disclosure relate to a plasma processing apparatus.

### BACKGROUND

A plasma processing apparatus is used for processing a substrate. As a type of plasma processing apparatus, it is known to excite gas using radio frequency such as VHF waves or UHF waves. Patent Document 1 below discloses such a plasma processing apparatus. The plasma processing apparatus of Patent Document 1 includes a processing container, a stage, an upper electrode, an introduction part, and a waveguide part. The stage is provided inside the processing container. The upper electrode is placed above the stage through a space inside the processing container. The introduction part is a radio frequency introduction part. The introduction part is provided at a transverse end of the space and extends in a circumferential direction around a center axis line of the processing container. The waveguide part is configured to supply radio frequency to the introduction part. The waveguide part includes a resonator that provides a waveguide path. The waveguide path of the resonator extends in the circumferential direction around the center axis line, extends in a direction in which the center axis line extends, and is connected to the introduction part.

### PRIOR ART DOCUMENT

### Patent Document

Patent Document 1: Japanese Patent laid-open publication No. 2020-92031

### SUMMARY

According to one embodiment of the present disclosure, there is provided a plasma processing apparatus including a chamber, a substrate support provided within the chamber, a discharger provided to discharge an electromagnetic wave into a plasma generation space, and a waveguide part configured to supply the electromagnetic wave to the discharger. The waveguide part includes a resonator that provides a waveguide path, and the resonator includes at least one slit having a longitudinal direction in a propagation direction in which the electromagnetic wave resonating within the resonator propagates in the waveguide path.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a plasma processing apparatus according to one exemplary embodiment.

FIG. 2 is a partially enlarged cross-sectional view illustrating a resonator and a connector of a plasma processing apparatus according to one exemplary embodiment.

FIG. 3 is a partially enlarged plan view illustrating a resonator and a connector of a plasma processing apparatus according to one exemplary embodiment.

FIG. 4 is a plan view illustrating an example of a first annular conductor plate that is adoptable in a plasma processing apparatus according to one exemplary embodiment.

FIG. 5 is a diagram illustrating an example of a second annular conductor plate that is adoptable in a plasma processing apparatus according to one exemplary embodiment.

FIG. 6 is a diagram illustrating another example of a first annular conductor plate that is adoptable in a plasma processing apparatus according to one exemplary embodiment.

FIG. 7 is a diagram illustrating a plasma processing apparatus according to another exemplary embodiment.

FIG. 8 is a diagram illustrating a plasma processing apparatus according to still another exemplary embodiment.

FIG. 9 is a diagram illustrating a plasma processing apparatus according to yet another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Reference will now be made in detail to various embodiments, examples of which are illustrated in the accompanying drawings. In each drawing, the same or corresponding configurations are denoted by the same reference numerals.

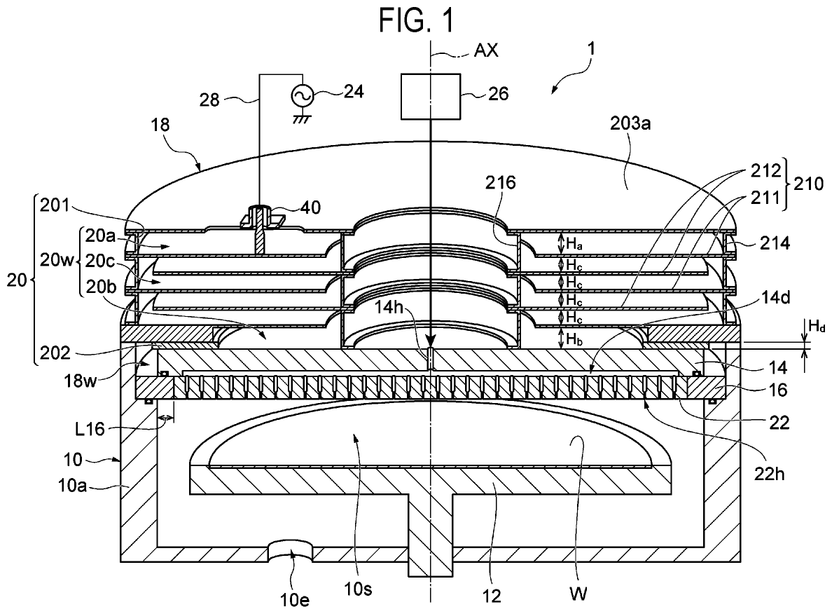

FIG. 1 is a diagram illustrating a plasma processing apparatus according to one exemplary embodiment. A plasma processing apparatus 1 illustrated in FIG. 1 includes a chamber 10, a substrate support 12, an upper electrode 14, a discharger 16, and a waveguide part 18.

The chamber 10 provides a processing space 10s therein. In the plasma processing apparatus 1, a substrate W is processed within the processing space 10s. The chamber 10 is formed of a metal such as aluminum and is grounded. The chamber 10 has a sidewall 10a and is open at an upper end thereof. The chamber 10 and the sidewall 10a may have a substantially cylindrical shape. The processing space 10s is provided inside the sidewall 10a. A center axis line of each of the chamber 10, the sidewall 10a, and the processing space 10s is an axis line AX. The chamber 10 may have a corrosion-resistant film on the surface thereof. The film having corrosion resistance may be a ceramic film containing an yttrium oxide film, an yttrium oxide fluoride film, an yttrium fluoride film, yttrium oxide, yttrium fluoride, or the like.

The bottom of the chamber 10 provides an exhaust port 10e. The exhaust port 10e has an exhaust device connected thereto. The exhaust device may include a vacuum pump, such as a dry pump and/or a turbo molecular pump, and an automatic pressure control valve.

The substrate support 12 is provided within the processing space 10s. The substrate support 12 is configured to substantially horizontally support the substrate W placed on the upper surface thereof. The substrate support 12 has an approximately disc shape. A center axis line of the substrate support 12 is the axis line AX.

The upper electrode 14 is provided above the substrate support 12 through the processing space 10s. The upper electrode 14 is made of a conductor such as a metal (e.g., aluminum) and has a substantially disc shape. A center axis line of the upper electrode 14 is the axis line AX.

The discharger 16 is provided to discharge an electromagnetic wave therefrom into a plasma generation space. In the plasma processing apparatus 1, the plasma generation space is included in the processing space 10s and a center axis line thereof is the axis line AX. In the plasma processing apparatus 1, gas in the processing space 10s is excited and plasma is generated by the electromagnetic wave discharged from the discharger 16 into the processing space 10s. The electromagnetic wave discharged from the discharger 16 into the processing space 10s may be radio frequency such as VHF waves or UHF waves. The discharger 16 is made of a dielectric material such as quartz, aluminum nitride, or aluminum oxide. The discharger 16 is provided at a transverse end of the processing space 10s and extends in a circumferential direction around the axis line AX. The discharger 16 may have an annular shape.

The waveguide part 18 is configured to supply the electromagnetic wave to the discharger 16. The electromagnetic wave is generated by a radio frequency power supply 24 which will be explained later. The electromagnetic wave is transmitted to the discharger 16 through the waveguide part 18 and is introduced into the processing space 10s from the discharger 16. The waveguide part 18 includes a resonator 20. Details of the resonator 20 will be described later.

In one embodiment, the plasma processing apparatus 1 may further include a shower plate 22. The shower plate 22 may be made of a metal such as aluminum. The discharger 16 extends so as to surround the shower plate 22. The discharger 16 and the shower plate 22 are disposed to close an opening at an upper end of the chamber 10. The shower plate 22 provides a plurality of gas holes 22h. The gas holes 22h extend in a thickness direction (vertical direction) of the shower plate 22 and penetrate the shower plate 22.

The shower plate 22 is provided below the upper electrode 14. The shower plate 22 and the upper electrode 14 define a gas diffusion space 14d therebetween. A center axis line of the gas diffusion space 14d may be the axis line AX. The gas holes 22h of the shower plate 22 are connected to the gas diffusion space 14d. In addition, the upper electrode 14 provides an inlet 14h. The inlet 14h may extend on the axis line AX. The inlet 14h is connected to the gas diffusion space 14d. A gas supplier 26 is connected to the gas diffusion space 14d. Gas output from the gas supplier 26 is supplied to the processing space 10s through the inlet 14h, the gas diffusion space 14d, and the gas holes 22h.

The plasma processing apparatus 1 may further include the radio frequency power supply 24. The radio frequency power supply 24 is electrically coupled to a waveguide path of the resonator 20 and is configured to generate radio frequency power, frequency of which is variable. The electromagnetic wave introduced into the chamber 10 is generated based on the radio frequency power generated by the radio frequency power supply 24. The radio frequency power supply 24 may be directly connected to the waveguide path of the resonator 20 by use of a coaxial line 28. That is, the radio frequency power supply 24 may be coupled to a waveguide path 20w of the resonator 20 without passing through a matcher for impedance matching.

The resonator 20 provides the waveguide path 20w. The waveguide path 20w may provide a cavity surrounded by a wall made of a conductor such as a metal (hereinafter referred to as a “conductor wall”). The conductor wall of the waveguide path 20w may be made of aluminum alloy, copper, nickel, stainless steel, etc. or may be coated with a low-resistance material such as silver, gold, or rhodium.

The resonator 20 includes a first stage 201 and a second stage 202. The first stage 201 constitutes one end of the waveguide path 20w of the resonator 20. In one embodiment, the first stage 201 may extend in a circumferential direction around the axis line AX.

The second stage 202 constitutes the other end of the waveguide path 20w of the resonator 20. The other end of the waveguide path 20w of the resonator 20 is electromagnetically coupled to the discharger 16. In the example illustrated in FIG. 1, the other end of the waveguide path 20w of the resonator 20 is connected to the discharger 16 through a waveguide path 18w of the waveguide part 18. The waveguide path 18w may be provided between the upper electrode 14 and the sidewall 10a of the chamber 10 and may extend around the axis line AX. The waveguide path 18w may be filled with a dielectric material.

In the resonator 20, a fundamental wave of an electromagnetic wave having a resonant frequency is reflected at the first stage 201 and the second stage 202 and resonates between the first stage 201 and the second stage 202. In one embodiment, in order to cause the electromagnetic wave (fundamental wave) to resonate between the first stage 201 and the second stage 202, the second stage 202 has a capacitance that shorts the waveguide path 20w at a frequency (resonant frequency) of the electromagnetic wave. In one embodiment, the second stage 202 may be provided in a circumferential direction around the axis line AX.

A resonator length L of the resonator 20 between the first stage 201 and the second stage 202 (a distance connecting the first stage 201 and the second stage 202 along the waveguide path 20w) may satisfy the following equation (1).

$$n λ g / 2 < L < ( n + 0.2 ) λ g / 2 \qquad ( 1 )$$

In equation (1), λg is the wavelength of the electromagnetic wave in the waveguide path 20w. In addition, n is an integer. Since the reactance of the second stage 202 is capacitive, the resonator length L may be set to a value slightly larger than nλg/2, as expressed in Equation (1).

In one embodiment, the waveguide path 20w of the resonator 20 may have a layered structure including an upper part 20a and a lower part 20b. The lower part 20b extends in a radially outward direction with respect to the axis line AX toward the second stage 202 of the resonator 20 around the axis line AX. The upper part 20a extends in a direction opposite to the radially outward direction from the first stage 201 above the lower part 20b and around the axis line AX. That is, the upper part 20a extends in a direction approaching the axis line AX from the first stage 201. The waveguide path 20w extends alternately in the radially outward direction and the direction opposite to the radially outward direction meanderingly from the first stage 201 to the second stage 202 around the axis line AX.

In one embodiment, the waveguide path 20w may further include a middle part 20c. The middle part 20c is provided between the upper part 20a and the lower part 20b. That is, the middle part 20c is provided below the upper part 20a and above the lower part 20b. One end of the middle part 20c is connected to an inner end of the upper part 20a, i.e., to the inner end of the upper part 20a with respect to the first stage 201. The other end of the middle part 20c is connected to an inner end of the lower part 20b, i.e., to the inner end of the lower part 20b with respect to the second stage 202. The middle part 20c may extend alternately in a radially outward direction and a direction opposite to the radially outward direction meanderingly around the axis line AX.

In one embodiment, the waveguide path 20w of the resonator 20 may include a plurality of annular conductor plates 210, an outer circumferential conductor part 214, and an inner circumferential conductor part 216 in order to form the above-described layered structure. Each of the annular conductor plates 210, the outer circumferential conductor part 214, and the inner circumferential conductor part 216 is a conductor wall of the resonator 20.

The plurality of annular conductor plates 210 is disposed such that centers (or center axes) thereof are located on the center axis line AX. The outer circumferential conductor part 214 constitutes an outer circumferential part of the resonator 20 in a radial direction with respect to the axis line AX and has a substantially cylindrical shape. The inner circumferential conductor part 216 constitutes an inner circumferential part of the resonator 20 in the radial direction with respect to the axis line AX and has a substantially cylindrical shape. The inner circumferential conductor part 216 is provided inside the outer circumferential conductor part 214.

In one embodiment, the plurality of annular conductor plates 210 may include one or more first annular conductor plates 211 and one or more second annular conductor plates 212. In the example illustrated in FIG. 1, the plurality of annular conductor plates 210 includes a plurality of first annular conductor plates 211 and a plurality of second annular conductor plates 212.

An outer edge of each of the first annular conductor plates 211 is fixed to the outer circumferential conductor part 214. An inner edge of each of the first annular conductor plates 211 is separated from the inner circumferential conductor part 216. An outer edge of each of the second annular conductor plates 212 is separated from the outer circumferential conductor part 214. An inner edge of each of the second annular conductor plates 212 is fixed to the inner circumferential conductor part 216. The first annular conductor plates 211 and the second annular conductor plates 212 are alternately arranged in a direction in which the axis line AX extends (hereinafter referred to as a vertical direction).

In the resonator 20 having such a layered structure, a propagation direction of an electromagnetic wave having a resonant frequency includes a radially outward direction with respect to the axis line AX and a direction opposite to the radially outward direction. Additionally, the propagation direction of the electromagnetic wave having the resonant frequency in the resonator 20 includes a vertical direction in an area along the inner circumferential conductor part 216 and an area along the outer circumferential conductor part 214.

In one embodiment, the second stage 202 may be formed of a dielectric material and may be an annular plate interposed between an upper conductor wall and a lower conductor wall (the upper electrode 14 in the example of FIG. 1) constituting the lower part 20b. In order to cause the electromagnetic wave to resonate between the first stage 201 and the second stage 202, the second stage 202 has an impedance lower than the waveguide path 20w in the lower part 20b with respect to the electromagnetic wave and, therefore, has a large capacitance. For this reason, an annular plate thickness H_{d} constituting the second stage 202 is smaller than a length H_{b} of the lower part 20b (or the height of the lower part 20b) in a vertical direction in which the axis line AX extends. Additionally, the length H_{b} is a length in the vertical direction of the waveguide path 20w in the lower part 20b and is a distance in the vertical direction between a pair of conductor walls (upper conductor wall and lower conductor wall) constituting the lower part 20b.

In one embodiment, the thickness H_{d} and the length H_{b} may satisfy the following Equation (2) or (3).

$$\frac{{H}_{b} \sqrt{{ε}_{r}}}{{H}_{d}} > 9 \qquad ( 2 )$$

$$\frac{{H}_{b} \sqrt{{ε}_{r}}}{{H}_{d}} > 19 \qquad ( 3 )$$

Here, εᵣ is a relative permittivity of a dielectric material constituting the second stage 202.

The resonator 20 supplies the electromagnetic wave from the second stage 202 thereof to the discharger 16 and causes the electromagnetic wave to resonate between the first stage 201 and the second stage 202. Therefore, an absolute value of a reflection coefficient Γ of the second stage 202 is less than 1 and has a large value close to 1. The reflection coefficient Γ is approximately expressed as Equation (4) below under the assumption that there is no reflection from below the first stage 201. When the absolute value of the reflection coefficient Γ is smaller than 1 and larger than 0.8, Equation (2) is derived from Equation (4). When the absolute value of the reflection coefficient Γ is smaller than 1 and larger than 0.9, Equation (3) is derived from Equation (4).

$$Γ = \frac{\frac{{H}_{d}}{{H}_{b} \sqrt{{ε}_{r}}} - 1}{\frac{{H}_{d}}{{H}_{b} \sqrt{{ε}_{r}}} + 1} \qquad ( 4 )$$

In one embodiment, the length H_{b} may be longer than a length H_{c} of the middle part 20c (the height of the middle part 20c) in a vertical direction. The length H_{c} is a length in the vertical direction of the waveguide path 20w in the middle part 20c and is a distance in the vertical direction between a pair of conductor walls (the upper conductor wall and the lower conductor wall) constituting the waveguide path 20w in the middle part 20c. In this embodiment, even if the thickness H_{d} is large, the thickness H_{d} may be set to be small relative to the length H_{b}. Therefore, while setting the impedance of the second stage 202 to be lower than the impedance of the waveguide path 20w in the lower part 20b, a plate thickness of an annular shape constituting the second stage 202 may be secured.

In one embodiment, a length L16 in a radial direction of an area of the discharger 16 exposed to the processing space 10s may be greater than the thickness H_{d}. In this case, a change in a resonant frequency of an electromagnetic wave before and after plasma ignition may be reduced.

In one embodiment, the plasma processing apparatus 1 may further include a connector 40 to introduce the electromagnetic wave into the waveguide path 20w. The connector 40 is part of the coaxial line 28. The radio frequency power supply 24 is coupled to the upper part 20a through the coaxial line 28 and the connector 40. The connector 40 may be coupled to the upper part 20a at a position separated from the axis line AX in a radial direction. Details of the connector 40 will be described later.

A length Hₐ of the upper part 20a (or a height of the upper part 20a) in a direction in which the axis line AX extends, i.e., in the vertical direction, may be longer than lengths of other parts of the waveguide path 20w in the vertical direction. In the example illustrated in FIG. 1, the length Hₐ is longer than the length H_{b} and the length H_{c}. In addition, the length Hₐ is a distance in the vertical direction between a pair of conductor walls (an upper conductor wall and a lower conductor wall) of the upper part 20a. The reactance of the upper part 20a changes depending on the length Hₐ of the upper part 20a. Therefore, it is possible to adjust the resonator length L according to the length Hₐ of the upper part 20a.

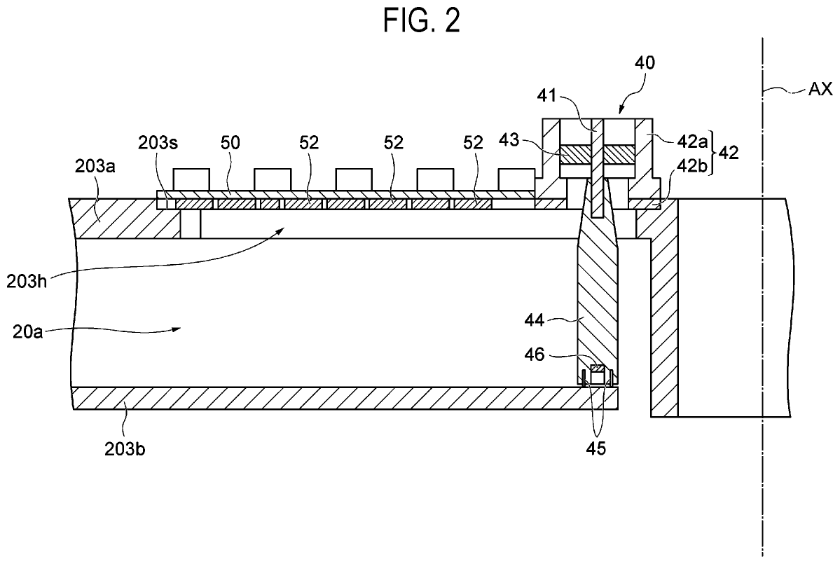

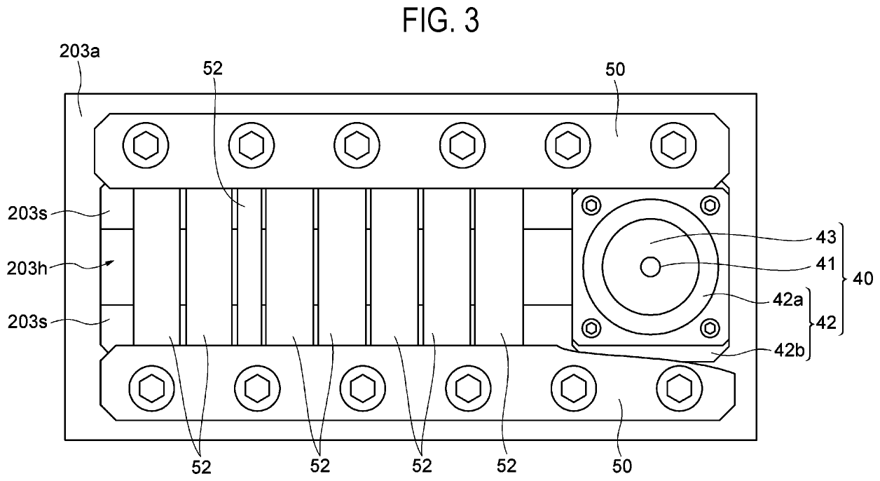

Hereinafter, an example of the structure of the connector 40 will be described with reference to FIGS. 2 and 3 together with FIG. 1. FIG. 2 is a partially enlarged cross-sectional view illustrating a resonator and a connector of a plasma processing apparatus according to one exemplary embodiment. FIG. 3 is a partially enlarged plan view illustrating a resonator and a connector of a plasma processing apparatus according to one exemplary embodiment. FIG. 3 shows a state in which one of a pair of pressing members is partially broken.

The connector 40 is coupled to the waveguide path 20w in the upper part 20a, as described above. The connector 40 may be configured to be movable in a radial direction with respect to the axis line AX. In this case, a position at which the connector 40 is coupled to the resonator 20 may be adjusted to a position at which reflection of an electromagnetic wave is suppressed (e.g., a position at which there is no reflection).

In one embodiment, the connector 40 may be a coaxial connector. In this case, the connector 40 may include a center conductor 41, an outer conductor 42, a spacer 43, a coupling rod 44, and one or more contact members 45.

The center conductor 41 has a rod shape. The center conductor 41 is electrically connected to the radio frequency power supply 24. The outer conductor 42 has a cylindrical shape. The center conductor 41 is coaxial with the outer conductor 42. The spacer 43 is made of an insulating material such as polytetrafluoroethylene. The spacer 43 is interposed between the center conductor 41 and the outer conductor 42.

A through hole 203h connected to a cavity of the upper part 20a is formed on an upper conductor wall 203a of the upper part 20a. The through hole 203h extends long in a radial direction with respect to the axis line AX. The upper conductor wall 203a provides a support surface 203s on both sides of the through hole 203h. The support surface 203s faces upward.

The coupling rod 44 is coupled to a lower end of the center conductor 41. The coupling rod 44 extends downward through the through hole 203h. The one or more contact members 45 are provided at a lower end of the coupling rod 44. The one or more contact members 45 may elastically contact a lower conductor wall 203b of the upper part 20a (i.e., the first annular conductor plate 211 extending at the highest position among the plurality of first annular conductor plates 211 described later). In one embodiment, the connector 40 may have a magnet 46 built into the coupling rod 44 to prevent the one or more contact members 45 from being detached from the coupling rod 44.

In one embodiment, the connector 40 may include a plurality of contact probes as the one or more contact members 45. Each of the contact probes includes a barrel, a spring disposed within an inner hole of the barrel, and a plunger that extends downward from the inner hole of the barrel and is pressurized downward by the spring. The plurality of contact probes may be arranged in a circumferential direction around a center axis line of the coupling rod 44. Alternatively, the connector 40 may have a spiral spring gasket or a diagonal wound coil spring as the one or more contact members 45.

The outer conductor 42 is in contact with the support surface 203s. The outer conductor 42 is movable in a radial direction on the support surface 203s. Accordingly, the connector 40 may adjust an engagement position with the upper part 20a in the radial direction thereof to suppress reflection of radio frequency power.

In a state in which the position of the connector 40 in the radial direction is set, the outer conductor 42 may be held between the support surface 203s and each of the pair of pressing members 50. Each of the pair of pressing members 50 has, e.g., a plate shape. The pair of pressing members 50 is fixed to the upper conductor wall 203a using a plurality of bolts. Additionally, in order to prevent leakage of an electromagnetic wave from the through hole 203h, one or more covers 52 may be disposed to cover the through hole 203h and may be held between the support surface 203s and each of the pair of pressing members 50.

In one embodiment, the outer conductor 42 may include a first member 42a and a second member 42b. The first member 42a is provided on the second member 42b and is fixed to the second member 42b. The first member 42a has a cylindrical shape. The spacer 43 is provided between the first member 42a and the center conductor 41. The second member 42b has a plate shape and provides a through hole continuous with an inner hole of the first member 42a. The second member 42b is held between the support surface 203s and each of the pair of pressing members 50.

In the plasma processing apparatus 1 described above, resonance of an electromagnetic wave is promoted between the first stage 201 and the second stage 202. Additionally, the first stage 201 and the second stage 202 promote uniform resonance of the electromagnetic wave in a circumferential direction. The resonated electromagnetic wave is discharged from the discharger 16 into the processing space 10s through the second stage 202 of the resonator 20. Therefore, according to the plasma processing apparatus 1, plasma is efficiently generated by the resonated electromagnetic wave between the first stage 201 and the second stage 202.

Additionally, the second stage 202 may be composed of a plurality of condensers arranged in a circumferential direction around the axis line AX. In each of the plurality of condensers, one of a pair of electrodes is disposed to be connected to the upper conductor wall of the lower part 20b, and the other of the pair of electrodes is disposed to be connected to the lower conductor wall of the lower part 20b. The plurality of condensers may be disposed at equal intervals. Alternatively, the second stage 202 may be composed of conductors arranged alternately with a plurality of gaps in the circumferential direction around the axis line AX.

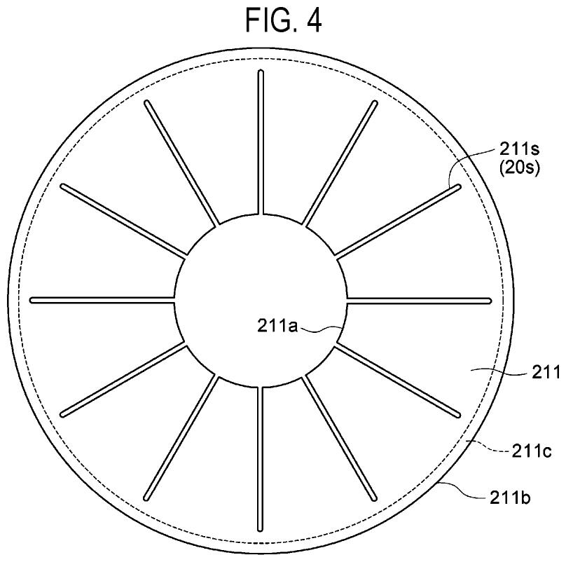

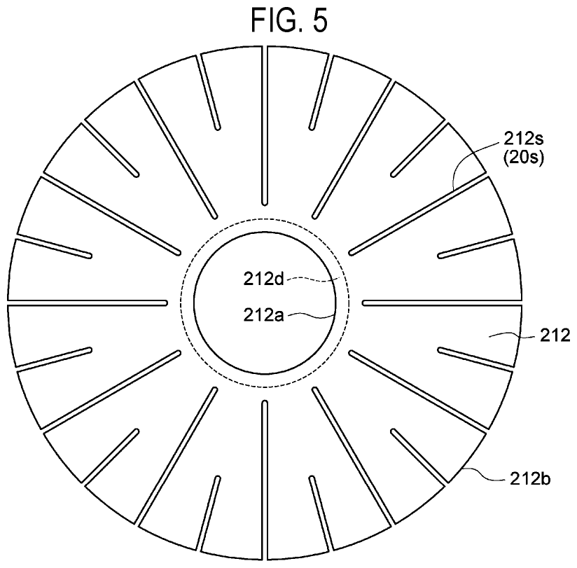

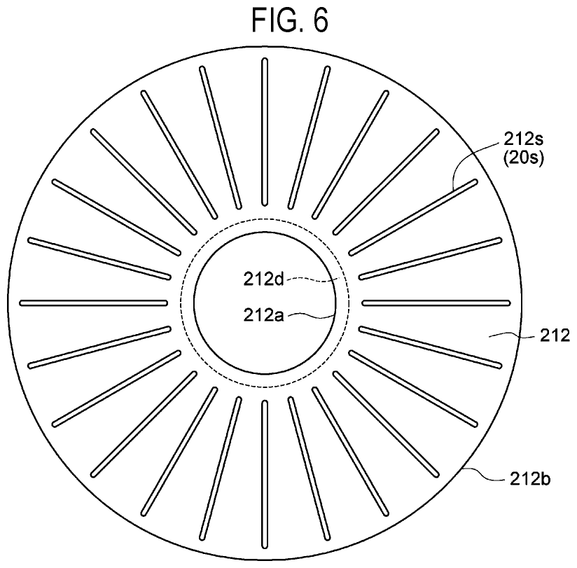

Hereinafter, additional details of the resonator 20 will be described with reference to FIGS. 4 to 6. FIG. 4 is a plan view illustrating an example of a first annular conductor plate that is adoptable in a plasma processing apparatus according to one exemplary embodiment. FIG. 5 is a diagram illustrating an example of a second annular conductor plate that is adoptable in a plasma processing apparatus according to one exemplary embodiment. FIG. 6 is a diagram illustrating another example of a first annular conductor plate that is adoptable in a plasma processing apparatus according to one exemplary embodiment.

The resonator 20 includes at least one slit 20s. In one embodiment, the resonator 20 includes a plurality of slits 20s. Each of the plurality of slits 20s has a longitudinal direction. The longitudinal direction of the plurality of slits 20s is a direction along a propagation direction of an electromagnetic wave resonating within the resonator 20 (a fundamental wave having a resonant frequency). In the plasma processing apparatus 1, the longitudinal direction of the plurality of slits 20s is a radial direction. The width of each of the plurality of slits 20s is twice or less the thickness of the annular conductive plate 210 in which the slit 20s is formed. In addition, the width of each of the plurality of slits 20s is a length in a transverse direction orthogonal to the longitudinal direction.

The plurality of slits 20s may include a plurality of first slits 211s and a plurality of second slits 212s. The plurality of first slits 211s is formed in at least one of the plurality of first annular conductive plates 211 or in each of the plurality of first annular conductive plates 211. As illustrated in FIG. 4, the plurality of first slits 211s is arranged in a circumferential direction around the axis line AX. Each of the plurality of first slits 211s may penetrate, as illustrated in FIG. 4, an inner edge 211a of the first annular conductor plate 211 in which the first slit 211s is formed. In this case, the first annular conductor plate 211 is fixed to the outer circumferential conductor part 214 in an outer edge area 211c including an outer edge 211b thereof but may be easily expanded and contracted at the inner edge 211a thereof. Therefore, even if the temperature of the first annular conductor plate 211 changes, generation of stress and deformation at the first annular conductor plate 211 is suppressed.

The plurality of second slits 212s is formed in at least one of the plurality of second annular conductive plates 212 or in each of the plurality of second annular conductive plates 212. As illustrated in FIG. 5, the plurality of second slits 212s is arranged in a circumferential direction around the axis line AX. Each of the plurality of second slits 212s may penetrate, as illustrated in FIG. 5, an outer edge 212b of the second annular conductor plate 212 in which the second slit 212s is formed. In this case, the second annular conductor plate 212 is fixed to the inner circumferential conductor part 216 in an inner edge area 212d including an inner edge 212a thereof but may be easily expanded and contracted at the outer edge 212b thereof. Therefore, even if the temperature of the second annular conductor plate 212 changes, generation of stress and deformation at the second annular conductor plate 212 is suppressed.

The plurality of second slits 212s arranged in a circumferential direction may include a first group of slits and a second group of slits. As illustrated in FIG. 5, a length of the first group of slits in a longitudinal direction and a length of the second group of slits in the longitudinal direction are different from each other, and the first group of slits and the second group of slits are arranged alternately in the circumferential direction.

Additionally, the plurality of first slits 211s arranged in a circumferential direction may also include a first group of slits and a second group of slits. In this case as well, a length of the first group of slits in a longitudinal direction and a length of the second group of slits in the longitudinal direction are different from each other, and the first group of slits and the second group of slits are arranged alternately in a circumferential direction.

As illustrated in FIG. 6, in another example, each of the plurality of second slits 212s may not penetrate inner and outer edges of the second annular conductor plate 212 in which the second slit 212a is formed. That is, an inner end of each of the plurality of second slits 212s in a radial direction may be located outside the inner edge 212a of the corresponding second annular conductive plate 212. In addition, an outer end of each of the plurality of second slits 212s in the radial direction may be located inside the outer edge 212b of the corresponding second annular conductive plate 212. Additionally, each of the plurality of first slits 211s may not penetrate inner and outer edges of the first annular conductor plate 211 in which the first slit 211s is formed. In this case, electromagnetic interference between an upper layer and a lower layer in the waveguide path 20w having the layered structure is suppressed.

The plurality of slits 20s interrupts propagation of harmonic waves in a direction intersecting a propagation direction of an electromagnetic wave (i.e., an electromagnetic wave having a resonant frequency). Accordingly, generation of an uneven harmonic mode in the direction intersecting the propagation direction of the electromagnetic wave is suppressed. In the plasma processing apparatus 1, the plurality of slits 20s does not hinder radio frequency current from flowing in a radial direction in the resonator 20. That is, the plurality of slits 20s does not interfere with propagation of the electromagnetic wave (i.e., the electromagnetic wave having the resonant frequency). Meanwhile, the plurality of slits 20s hinders propagation of the harmonic waves in a circumferential direction. Therefore, according to the plasma processing apparatus 1, generation of the uneven harmonic mode in the circumferential direction is suppressed. Therefore, according to the plasma processing apparatus 1, uniform plasma may be formed in the circumferential direction.

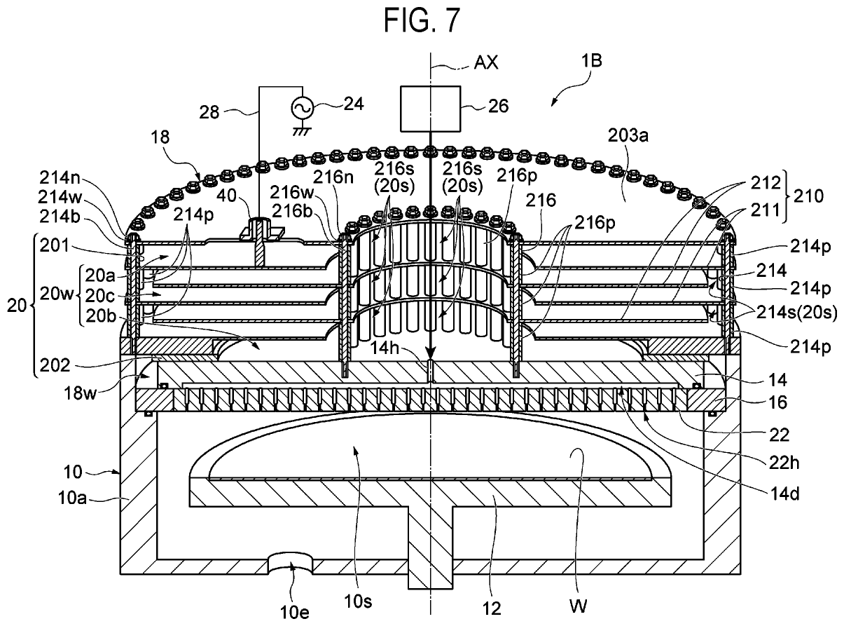

Hereinafter, a plasma processing apparatus according to another exemplary embodiment will be described with reference to FIG. 7. FIG. 7 is a diagram illustrating a plasma processing apparatus according to another exemplary embodiment. Hereinafter, a plasma processing apparatus 1B illustrated in FIG. 7 will be described from the viewpoint of differences from the plasma processing apparatus 1.

In the plasma processing apparatus 1, a plurality of slits 20s is provided not in a plurality of annular conductor plates 210 but in an outer circumferential conductor part 214 and an inner circumferential conductor part 216. However, even in the plasma processing apparatus 1i, as in the plasma processing apparatus 1, the plurality of slits 20s may be formed in at least one of the plurality of annular conductor plates 210.

The outer circumferential conductor part 214 includes a plurality of pillars 214p. The plurality of pillars 214p is made of a conductor such as a metal. The plurality of pillars 214p extends in a direction in which an axis line AX extends (i.e., a vertical direction). The plurality of pillars 214p is arranged at intervals in a circumferential direction around the axis line AX. That is, the plurality of pillars 214p is provided so that a plurality of gaps 214s and the plurality of pillars 214p are alternately arranged in the circumferential direction around the axis line AX. Each of the plurality of gaps 214s has a longitudinal direction in a direction in which the axis line AX extends. In the plasma processing apparatus 1, the plurality of slits 20s includes the plurality of gaps 214s. The width of each of the plurality of gaps 214s may be 1/100 or less of the wavelength of an electromagnetic wave resonating within the resonator 20 (a fundamental wave having a resonant frequency).

Each of the plurality of pillars 214p is divided into a plurality of portions aligned in a vertical direction. The plurality of portions of each of the plurality of pillars 214p is alternately arranged with a plurality of first annular conductive plates 211 in the vertical direction. The plurality of portions of each of the plurality of pillars 214p, the plurality of first annular conductive plates 211, and an upper conductive wall 203a are fixed so as to be electrically conductive with each other.

In one embodiment, each of the plurality of portions of each of the plurality of pillars 214p has a cylindrical shape. A bolt 214b is passed through the plurality of portions of each of the plurality of pillars 214p. A lower end of the bolt 214b is screwed into a screw hole formed in the first annular conductive plate 211 extending at the lowest position among the plurality of first annular conductive plates 211. An upper end of the bolt 214b is located above an upper conductor wall 203a. A nut 214n is screwed onto the upper end of the bolt 214b. The nut 214n presses the upper conductor wall 203a through a washer 214w to fix the plurality of portions of each of the plurality of pillars 214p, the plurality of first annular conductor plates 211, and the upper conductor wall 203a to each other.

The inner circumferential conductor part 216 includes a plurality of pillars 216p. The plurality of pillars 216p is made of a conductor such as a metal. The plurality of pillars 216p extends in a direction in which the axis line AX extends (i.e., a vertical direction). The plurality of pillars 216p is arranged at intervals in a circumferential direction around the axis line AX. That is, the plurality of pillars 216p is provided so that a plurality of gaps 216s and the plurality of pillars 216p are alternately arranged in the circumferential direction around the axis line AX. Each of the plurality of gaps 216s has a longitudinal direction in a direction in which the axis line AX extends. In the plasma processing apparatus 1, the plurality of slits 20s includes the plurality of gaps 216s. The width of each of the plurality of gaps 216s may be 1/100 or less of the wavelength of an electromagnetic wave resonating within the resonator 20 (a fundamental wave having a resonant frequency).

Each of the plurality of pillars 216p is divided into a plurality of portions aligned in a vertical direction. The plurality of portions of each of the plurality of pillars 216p is alternately arranged with a plurality of second annular conductive plates 212 in the vertical direction. The plurality of portions of each of the plurality of pillars 216p, the plurality of second annular conductive plates 212, and an upper conductive wall 203a are fixed so as to be electrically conductive with each other.

In one embodiment, each of the plurality of portions of each of the plurality of pillars 216p has a cylindrical shape. A bolt 216b is passed through the plurality of portions of each of the plurality of pillars 216p. A lower end of the bolt 216b is screwed into a screw hole formed in the upper electrode 14. An upper end of the bolt 216b is located above the upper conductor wall 203a. A nut 216n is screwed onto the upper end of the bolt 216b. The nut 216n presses the upper conductor wall 203a through a washer 216w to fix the plurality of portions of each of the plurality of pillars 216p, the plurality of second annular conductor plates 212, and the upper conductor wall 203a to each other.

Even in the plasma processing apparatus 1B, the plurality of slits 20s does not hinder radio frequency current from flowing in a radial direction in the resonator 20. That is, the plurality of slits 20s does not interfere with propagation of the electromagnetic wave (i.e., the electromagnetic wave having the resonant frequency). Meanwhile, the plurality of slits 20s hinders propagation of harmonic waves in a circumferential direction. Therefore, according to the plasma processing apparatus 1, generation of an uneven harmonic mode in the circumferential direction is suppressed. Therefore, according to the plasma processing apparatus 1B, uniform plasma may be formed in the circumferential direction.

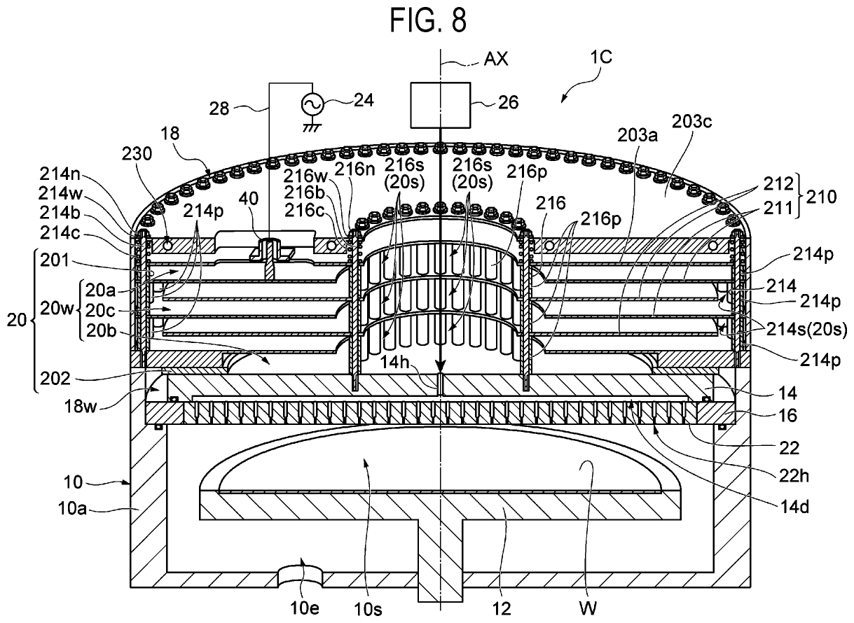

Hereinafter, a plasma processing apparatus according to another exemplary embodiment will be described with reference to FIG. 8. FIG. 8 is a diagram illustrating a plasma processing apparatus according to another exemplary embodiment. Hereinafter, a plasma processing apparatus 1C illustrated in FIG. 8 will be described from the viewpoint of differences from the plasma processing apparatus 1B.

In the plasma processing apparatus 1C, a resonator 20 further includes a cooling plate 203c. The cooling plate 203c extends above an upper conductor wall 203a. An inner edge and an outer edge of the upper conductor wall 203a are fixed to an inner circumferential conductor part 216 and an outer circumferential conductor part 214, respectively. In the plasma processing apparatus 1C, one or more contact members 45 of a connector 40 are in contact with a first annular conductive plate 211.

In the plasma processing apparatus 1C, a refrigerant flow path 230 is formed in the cooling plate 203c. A refrigerant is supplied to the refrigerant flow path 230 from a chiller unit. In the plasma processing apparatus 1C, the cooling plate 203c is cooled by the refrigerant. Therefore, it is possible to dispose, on the cooling plate 203c, components that are not suitable to be disposed in a high temperature environment, such as electronic components.

In the plasma processing apparatus 1C, a coil spring 214c is provided around a bolt 214b and between the upper conductor wall 203a and the cooling plate 203c. Even if the temperature of the resonator 20 changes, a plurality of portions of each of a plurality of pillars 214p, the plurality of first annular conductor plates 211, and the upper conductor wall 203a are more surely conducted by the coil spring 214c.

Additionally, in the plasma processing apparatus 1C, a coil spring 216c is provided around a bolt 216b and between the upper conductor wall 203a and the cooling plate 203c. Even if the temperature of the resonator 20 changes, a plurality of portions of each of a plurality of pillars 216p, a plurality of second annular conductor plates 212, and the upper conductor wall 203a are more surely conducted by the coil spring 216c.

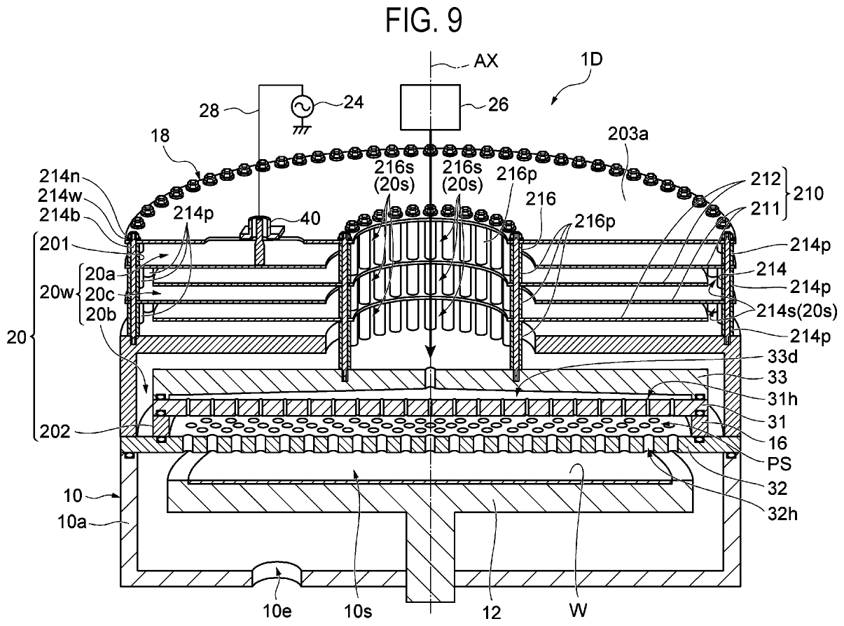

Hereinafter, a plasma processing apparatus according to another exemplary embodiment will be described with reference to FIG. 9. FIG. 9 is a diagram illustrating a plasma processing apparatus according to yet another exemplary embodiment. Hereinafter, the plasma processing apparatus 1D illustrated in FIG. 9 will be described from the viewpoint of differences from the plasma processing apparatus 1B.

The plasma processing apparatus 1D includes a first electrode 31 and a second electrode 32, in addition to a chamber 10, a substrate support 12, a discharger 16, and a waveguide part 18.

The first electrode 31 is provided above a processing space 10s. The first electrode 31 is formed of a conductor such as a metal (e.g., aluminum) and has a substantially disc shape. A center axis line of the first electrode 31 is an axis line AX. The first electrode 31 may provide a plurality of gas holes 31h for introducing gas into a plasma generation space PS which will be described later. The plurality of gas holes 31h extends in a thickness direction (vertical direction) of the first electrode 31 and penetrates the first electrode 31.

The second electrode 32 is provided above the processing space 10s and below the first electrode 31. The second electrode 32 may extend substantially parallel to the first electrode 31. The second electrode 32 is formed of a conductor such as a metal (e.g., aluminum) and has a substantially disc shape. A center axis line of the second electrode 32 is the axis line AX. The second electrode 32 closes an opening of an upper end of the chamber 10. That is, the second electrode 32 partitions the processing space 10s from above.

The second electrode 32 provides the plasma generation space PS between the first electrode 31 and the second electrode 32. A center axis line of the plasma generation space PS is the axis line AX. In the plasma generation space PS, plasma is generated from gas by an electromagnetic wave discharged from the discharger 16. The second electrode 32 provides a plurality of through holes 32h in order to guide active species from plasma in the plasma generation space PS to the processing space 10s. The plurality of through holes 32h extends in a thickness direction (vertical direction) of the second electrode 32 and penetrates the second electrode 32. The cross-sectional area of the plurality of through holes 32h is configured to suppress deactivation of the active species when the active species pass through the plurality of through holes 32h and is relatively large.

In the plasma processing apparatus 1D, the discharger 16 is configured to discharge an electromagnetic wave into the plasma generation space PS in order to generate plasma in the plasma generation space PS. The discharger 16 may extend in a circumferential direction around the axis line AX so as to surround the plasma generation space PS. The discharger 16 may have a ring shape. The discharger 16 may be held between a peripheral edge of the first electrode 31 and a peripheral edge of the second electrode 32. In the plasma processing apparatus 1D, an electromagnetic wave propagates to the discharger 16 through the resonator 20 and is introduced from the discharger 16 into the plasma generation space PS.

The plasma processing apparatus 1D may further include a cover 33. The cover 33 is provided on the first electrode 31. The cover 33 is made of a conductor such as aluminum and has a substantially disc shape. A center axis line of the cover 33 is the axis line AX.

The cover 33 provides a gas diffusion space 33d between the first electrode 31 and the cover 33. A gas supplier 26 is connected to the gas diffusion space 33d. Gas output from the gas supplier 26 is supplied to the plasma generation space PS through the gas diffusion space 33d and the plurality of gas holes 31h.

In the plasma processing apparatus 1D as well, the waveguide part 18 includes the resonator 20. In the plasma processing apparatus 1D, a second stage 202 of a resonator 20 is a boundary between the discharger 16 and a waveguide path 20w of the resonator 20.

The resonator 20 having a plurality of slits 20s is adoptable not only in an apparatus for generating plasma within the processing space 10s, but also in an apparatus for generating plasma in the plasma generating space PS separated from the processing space 10s, such as the plasma processing apparatus 1D.

Although various exemplary embodiments have been described above, the present disclosure is not limited to the above-described exemplary embodiments, and various additions, omissions, substitutions, and changes may be made. In addition, it is possible to form other embodiments by combining elements from other embodiments.

For example, in each of the plasma processing apparatuses 1B, 1C, and 1D, only one of the outer circumferential conductor part 214 and the inner circumferential conductor part 216 may provide the plurality of slits 20s. That is, only one of the outer circumferential conductor part 214 and the inner circumferential conductor part 216 may be composed of a plurality of pillars. In this case, the other one of the outer circumferential conductor part 214 and the inner circumferential conductor part 216 may be formed of a conductor wall having a cylindrical shape.

Here, various exemplary embodiments included in the present disclosure are described in [E1] to [E18] below.

### [E1]

A plasma processing apparatus, including:
a chamber;
a substrate support provided within the chamber;
a discharger provided to discharge an electromagnetic wave into a plasma generation space; and
a waveguide part configured to supply the electromagnetic wave to the discharger,
wherein the waveguide part includes a resonator that provides a waveguide path, and
wherein the resonator includes at least one slit having a longitudinal direction in a propagation direction in which the electromagnetic wave resonating within the resonator propagates in the waveguide path.

### [E2]

The plasma processing apparatus according to E1, wherein the discharger is provided at a transverse end of the plasma generation space and extends in a circumferential direction around a center axis line of the plasma generation space, and
wherein the resonator is configured to propagate the electromagnetic wave in the waveguide path in a radially outward direction with respect to the center axis line, in a direction opposite to the radially outward direction, and in a direction in which the center axis line extends, and the longitudinal direction of the at least one slit of the resonator is the radial direction or the direction in which the center axis line extends.

### [E3]

A plasma processing apparatus, including:
a chamber;
a substrate support provided within the chamber,
a discharger provided to discharge an electromagnetic wave into a plasma generation space and extending in a circumferential direction around a center axis line of the plasma generation space; and
a waveguide part configured to supply the electromagnetic wave to the discharger,
wherein the waveguide part includes a resonator that provides a waveguide path, and
wherein the resonator
is configured such that a propagation direction of the electromagnetic wave resonating within the resonator in the waveguide path is a radially outward direction with respect to the center axis line and a direction opposite to the radially outward direction, and
includes at least one slit having a longitudinal direction in a direction intersecting the circumferential direction.

### [E4]

The plasma processing apparatus according to E2 or E3, wherein the resonator includes a first stage and a second stage at which the electromagnetic wave is reflected and between which the electromagnetic wave resonates,
wherein the first stage and the second stage extend in a circumferential direction around the center axis line,
wherein an end of the waveguide path of the resonator including the second stage is disposed below the first stage and is electromagnetically coupled to the discharger, and
wherein the waveguide path of the resonator has a layered structure including
a lower part extending in the radially outward direction with respect to the center axis line toward the second stage around the center axis line, and
an upper part extending in the direction opposite to the radially outward direction from the first stage above the lower part and around the center axis line, and
extends alternately in the radially outward direction and the direction opposite to the radially outward direction meanderingly from the first stage to the second stage around the center axis line.

### [E5]

The plasma processing apparatus according to E4, wherein the waveguide path of the resonator includes a plurality of annular conductor plates disposed such that centers thereof are located on the center axis line, an outer circumferential conductor part constituting an outer circumferential part of the resonator in the radial direction, and an inner circumferential conductor part constituting an inner circumference of the resonator in the radial direction, and
wherein the plurality of annular conductor plates includes
a first annular conductor plate having an outer edge fixed to the outer circumferential conductor part and having an inner edge separated from the inner circumferential conductor part, and
a second annular conductor plate having an outer edge separated from the outer circumferential conductor part and having an inner edge fixed to the inner circumferential conductor part.

### [E6]

The plasma processing apparatus according to E5, wherein the at least one slit is formed in at least one annular conductor plate among the plurality of annular conductor plates, and
wherein the longitudinal direction of the at least one slit of the resonator is the radial direction.

### [E7]

The plasma processing apparatus according to E6, wherein the at least one slit includes an inner end and an outer end in the radial direction,
wherein the inner end is located outside the inner edge of the at least one annular conductor plate, and
wherein the outer end is located inside an outer edge of the at least one annular conductor plate.

### [E8]

The plasma processing apparatus according to E6 or E7, wherein a width of the at least one slit is twice or less a thickness of the at least one annular conductor plate.

### [E9]

The plasma processing apparatus according to any one of E6 to E8, wherein a plurality of slits is formed in the at least one annular conductor plate as the at least one slit, and
wherein the plurality of slits is arranged in the circumferential direction around the center axis line.

### [E10]

The plasma processing apparatus according to E9, wherein the plurality of slits includes a first group of slits and a second group of slits arranged alternately in the circumferential direction, and
wherein a length of the first group of slits in the longitudinal direction and a length of the second group of slits in the longitudinal direction are different from each other.

### [E11]

The plasma processing apparatus according to any one of E6 to E10, wherein a plurality of first slits arranged in the circumferential direction around the center axis line is formed in the first annular conductor plate as the at least one slit, and
wherein a plurality of second slits arranged in the circumferential direction around the center axis line is formed in the second annular conductive plate as the at least one slit.

### [E12]

The plasma processing apparatus according to E11, wherein each of the plurality of first slits penetrates an inner edge of the first annular conductor plate, and
wherein each of the plurality of second slits penetrates an outer edge of the second annular conductor plate.

### [E13]

The plasma processing apparatus according to E5, wherein at least one of the outer circumferential conductor part or the inner circumferential conductor part includes a plurality of pillars, and
wherein the plurality of pillars extends in a direction in which the center axis line extends and is arranged at intervals in the circumferential direction around the center axis line so as to provide a plurality of slits therebetween as the at least one slit.

### [E14]

The plasma processing apparatus according to E13, wherein the width of the slit is 1/100 or less of a wavelength of the electromagnetic wave resonating within the resonator.

### [E15]

The plasma processing apparatus according to any one of E4 to E14, further including a connector for introducing the electromagnetic wave into the waveguide path of the resonator,
wherein the connector is coupled to the upper part at a position separated in a radial direction from the center axis line.

### [E16]

The plasma processing apparatus according to any one of E1 to E15, wherein the chamber provides a processing space therein, and
wherein the processing space includes the plasma generation space.

### [E17]

The plasma processing apparatus according to E16, further including a shower plate disposed above the processing space,
wherein the discharger extends so as to surround the shower plate.

### [E18]

The plasma processing apparatus according to any one of E1 to E17, further including a radio frequency power supply electrically coupled to the waveguide path of the resonator and configured to generate radio frequency power, frequency of which is variable, and supply the electromagnetic wave into the waveguide path.

According to one exemplary embodiment, it is possible to suppress propagation of harmonic waves in a direction intersecting a propagation direction of an electromagnetic wave in the resonator of the plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber;
a substrate support provided within the chamber;
a discharger provided to discharge an electromagnetic wave into a plasma generation space; and
a waveguide part configured to supply the electromagnetic wave to the discharger,
wherein the waveguide part includes a resonator that provides a waveguide path, and
wherein the resonator includes at least one slit having a longitudinal direction in a propagation direction in which the electromagnetic wave resonating within the resonator propagates in the waveguide path.

2. The plasma processing apparatus of claim 1, wherein the discharger is provided at a transverse end of the plasma generation space and extends in a circumferential direction around a center axis line of the plasma generation space, and
wherein the resonator is configured to propagate the electromagnetic wave in the waveguide path in a radially outward direction with respect to the center axis line, in a direction opposite to the radially outward direction, and in a direction in which the center axis line extends, and the longitudinal direction of the at least one slit of the resonator is the radial direction or the direction in which the center axis line extends.

3. A plasma processing apparatus, comprising:
a chamber;
a substrate support provided within the chamber,
a discharger provided to discharge an electromagnetic wave into a plasma generation space and extending in a circumferential direction around a center axis line of the plasma generation space; and
a waveguide part configured to supply the electromagnetic wave to the discharger,
wherein the waveguide part includes a resonator that provides a waveguide path, and
wherein the resonator is configured such that a propagation direction of the electromagnetic wave resonating within the resonator in the waveguide path is a radially outward direction with respect to the center axis line and a direction opposite to the radially outward direction, and includes at least one slit having a longitudinal direction in a direction intersecting the circumferential direction.

4. The plasma processing apparatus of claim 2, wherein the resonator includes a first stage and a second stage at which the electromagnetic wave is reflected and between which the electromagnetic wave resonates,
wherein the first stage and the second stage extend in a circumferential direction around the center axis line,
wherein an end of the waveguide path of the resonator including the second stage is disposed below the first stage and is electromagnetically coupled to the discharger, and
wherein the waveguide path of the resonator has a layered structure including a lower part extending in the radially outward direction with respect to the center axis line toward the second stage around the center axis line, and an upper part extending in the direction opposite to the radially outward direction from the first stage above the lower part and around the center axis line, and extends alternately in the radially outward direction and the direction opposite to the radially outward direction meanderingly from the first stage to the second stage around the center axis line.

5. The plasma processing apparatus of claim 4, wherein the waveguide path of the resonator includes a plurality of annular conductor plates disposed such that centers thereof are located on the center axis line, an outer circumferential conductor part constituting an outer circumferential part of the resonator in the radial direction, and an inner circumferential conductor part constituting an inner circumference of the resonator in the radial direction, and
wherein the plurality of annular conductor plates includes
a first annular conductor plate having an outer edge fixed to the outer circumferential conductor part and having an inner edge separated from the inner circumferential conductor part, and
a second annular conductor plate having an outer edge separated from the outer circumferential conductor part and having an inner edge fixed to the inner circumferential conductor part.

6. The plasma processing apparatus of claim 5, wherein the at least one slit is formed in at least one annular conductor plate among the plurality of annular conductor plates, and
wherein the longitudinal direction of the at least one slit of the resonator is the radial direction.

7. The plasma processing apparatus of claim 6, wherein the at least one slit includes an inner end and an outer end in the radial direction,
wherein the inner end is located outside the inner edge of the at least one annular conductor plate, and
wherein the outer end is located inside an outer edge of the at least one annular conductor plate.

8. The plasma processing apparatus of claim 6, wherein a width of the at least one slit is twice or less a thickness of the at least one annular conductor plate.

9. The plasma processing apparatus of claim 6, wherein a plurality of slits is formed in the at least one annular conductor plate as the at least one slit, and
wherein the plurality of slits is arranged in the circumferential direction around the center axis line.

10. The plasma processing apparatus of claim 9, wherein the plurality of slits includes a first group of slits and a second group of slits arranged alternately in the circumferential direction, and
wherein a length of the first group of slits in the longitudinal direction and a length of the second group of slits in the longitudinal direction are different from each other.

11. The plasma processing apparatus of claim 6, wherein a plurality of first slits arranged in the circumferential direction around the center axis line is formed in the first annular conductor plate as the at least one slit, and
wherein a plurality of second slits arranged in the circumferential direction around the center axis line is formed in the second annular conductive plate as the at least one slit.

12. The plasma processing apparatus of claim 11, wherein each of the plurality of first slits penetrates an inner edge of the first annular conductor plate, and
wherein each of the plurality of second slits penetrates an outer edge of the second annular conductor plate.

13. The plasma processing apparatus of claim 5, wherein at least one of the outer circumferential conductor part or the inner circumferential conductor part includes a plurality of pillars, and
wherein the plurality of pillars extends in a direction in which the center axis line extends and is arranged at intervals in the circumferential direction around the center axis line so as to provide a plurality of slits therebetween as the at least one slit.

14. The plasma processing apparatus of claim 13, wherein a width of the slit is 1/100 or less of a wavelength of the electromagnetic wave resonating within the resonator.

15. The plasma processing apparatus of claim 4, further comprising a connector for introducing the electromagnetic wave into the waveguide path of the resonator,
wherein the connector is coupled to the upper part at a position separated in a radial direction from the center axis line.

16. The plasma processing apparatus of claim 1, wherein the chamber provides a processing space therein, and
wherein the processing space includes the plasma generation space.

17. The plasma processing apparatus of claim 16, further comprising a shower plate disposed above the processing space,
wherein the discharger extends so as to surround the shower plate.

18. The plasma processing apparatus of claim 1, further comprising a radio frequency power supply electrically coupled to the waveguide path of the resonator and configured to generate radio frequency power, frequency of which is variable, and supply the electromagnetic wave into the waveguide path.

19. The plasma processing apparatus of claim 3, wherein the resonator includes a first stage and a second stage at which the electromagnetic wave is reflected and between which the electromagnetic wave resonates,
wherein the first stage and the second stage extend in a circumferential direction around the center axis line,
wherein an end of the waveguide path of the resonator including the second stage is disposed below the first stage and is electromagnetically coupled to the discharger, and
wherein the waveguide path of the resonator has a layered structure including a lower part extending in the radially outward direction with respect to the center axis line toward the second stage around the center axis line, and an upper part extending in the direction opposite to the radially outward direction from the first stage above the lower part and around the center axis line, and extends alternately in the radially outward direction and the direction opposite to the radially outward direction meanderingly from the first stage to the second stage around the center axis line.
